(19) United States
(12) Patent Application Publication
(10) Pub. No.: US 2002/0117750 A1
(43) Pub. Date: Aug. 29, 2002

(54) Semiconductor device

(76) Inventors: Yasuyuki Kojima, Hitachi (JP); Seigou Yukutake, Hitachinaka (JP); Minehiro Nemoto, Hitachi (JP); Nobuyasu Kanekawa, Hitachi (JP); Noboru Akiyama, Hitachi (JP)

Correspondence Address: GREGORY E. MONTONE, ANTONELLI, TERRY, STOUT & KRAUS, SUITE 1800, 1300 N. SEVENTEENTH ST., ARLINGTON, VA, 22209, US

(21) Appl. No.: 09/964,764

(22) Filed: Sep. 28, 2001

(30) Foreign Application Priority Data
Feb. 23, 2001 (JP) 2001-048877

(51) Int. Cl. H01L 23/495; H01L 23/34

(52) U.S. Cl. 257/724; 257/728; 257/532; 257/676; 257/666; 257/678; 257/687

(57) ABSTRACT

In a semiconductor device, an imbedded insulating layer is formed in a semiconductor substrate. A plurality of electric circuits are formed on the imbedded insulating layer so as to be insulated each other, and are capacitively coupled through the semiconductor substrate. Wiring layers are formed on the electric circuits, and include inside electrodes which are capacitively coupled to the electric circuits. The electric circuits are connected through capacitors which are formed through the semiconductor substrate, and through capacitors which are formed through the electrodes.

### BACKGROUND OF THE INVENTION

The present invention relates to a semiconductor device, and more particularly to a semiconductor device incorporating an insulating switch circuit and its application circuit.

It is possible to secure a safety of an operator or equipment or to reduce noises, by electrically insulating or isolating a plurality of electrical circuits. A semiconductor device and its application circuit device are proposed in which an insulating switch using an insulating capacitor or an isolator in place of the conventional discrete transformer or photo-coupler is formed in a semiconductor substrate as the insulation or isolation means. Such devices are disclosed in U.S. Pat. No. 4,339,668 entitled “Monolithically integrated circuit of high dielectric strength for electrically coupling isolated circuits”, and WO98/44687 entitled “Monolithic insulating coupler and a monolithic circuit interface circuit and a modem device using the same”, for example. These are effective for reducing the sizes of the devices using the semiconductors.

The semiconductor devices are always requested to be made smaller in size and lower in cost. When the conventional technique is studied in this point of view, it has a problem such that the insulating capacitor formed on a semiconductor substrate occupies a large area. That is, more than two insulating capacitors are required for transmitting a signal, so that in order to form two capacitors each having 1 pF and a breakdown voltage of 1,000 VAC, an area of about 0.3 mm×0.6 mm is required. Further, this area is almost unchanged even if the wiring rule in the semiconductor is changed.

### SUMMARY OF THE INVENTION

The present invention has been done in view of the above problem, and provides a semiconductor device in which the insulating capacitor can be formed in a small mounting area.

In order to solve the above problem, the present invention is arranged to comprise:

an imbedded insulating layer formed in a semiconductor substrate;

at least two electric circuits formed on the imbedded insulating layer so as to be insulated each other, and capacitively coupled through the semiconductor substrate; and

a wiring layer formed on the electric circuits, and including inside electrodes which are capacitively coupled to the electric circuits,

wherein the electric circuits are coupled through capacitors formed through the semiconductor substrate, and capacitors formed through the electrodes.

Further, one of the electric circuits may be a drive circuit for generating an alternating wave, and another electric circuit may be a charge pump circuit for driving a switch circuit for turning on and off a power source of the other electric circuit.

### BRIEF DESCRIPTION OF THE DRAWINGS

FIG. 1 is a plan view of a semiconductor device according to a first embodiment of the present invention;

FIG. 2 shows a cross-section along a line A-A in FIG. 1;

FIG. 3 shows an example in which the semiconductor device is applied to an insulating switch;

FIG. 4 shows diagrams explaining the operation of the circuit shown in FIG. 3;

FIG. 5 shows another example in which the semiconductor device is applied to the insulating switch;

FIG. 6 shows diagrams explaining the operation of the circuit shown in FIG. 5;

FIG. 7 shows still another example in which the semiconductor device is applied to the insulating switch;

FIG. 8 shows diagrams explaining the operation of the circuit shown in FIG. 7;

FIG. 9 shows still further example in which the semiconductor device is applied to the insulating switch;

FIG. 10 shows still another example in which the semiconductor device is applied to the insulating switch;

FIG. 11 is a plan view of a semiconductor device according to a second embodiment of the present invention;

FIG. 12 is a plan view of a semiconductor device according to a third embodiment of the present invention;

FIG. 13 is a diagram explaining an example in which a semiconductor device for modem according to the present invention is used in a modem device;

FIG. 14 shows an internal structure of the semiconductor device for modem; and

FIG. 15 shows an example of a network system which uses a transceiver LSI using a semiconductor device according to the present invention.

### DETAILED DESCRIPTION OF THE EMBODIMENTS

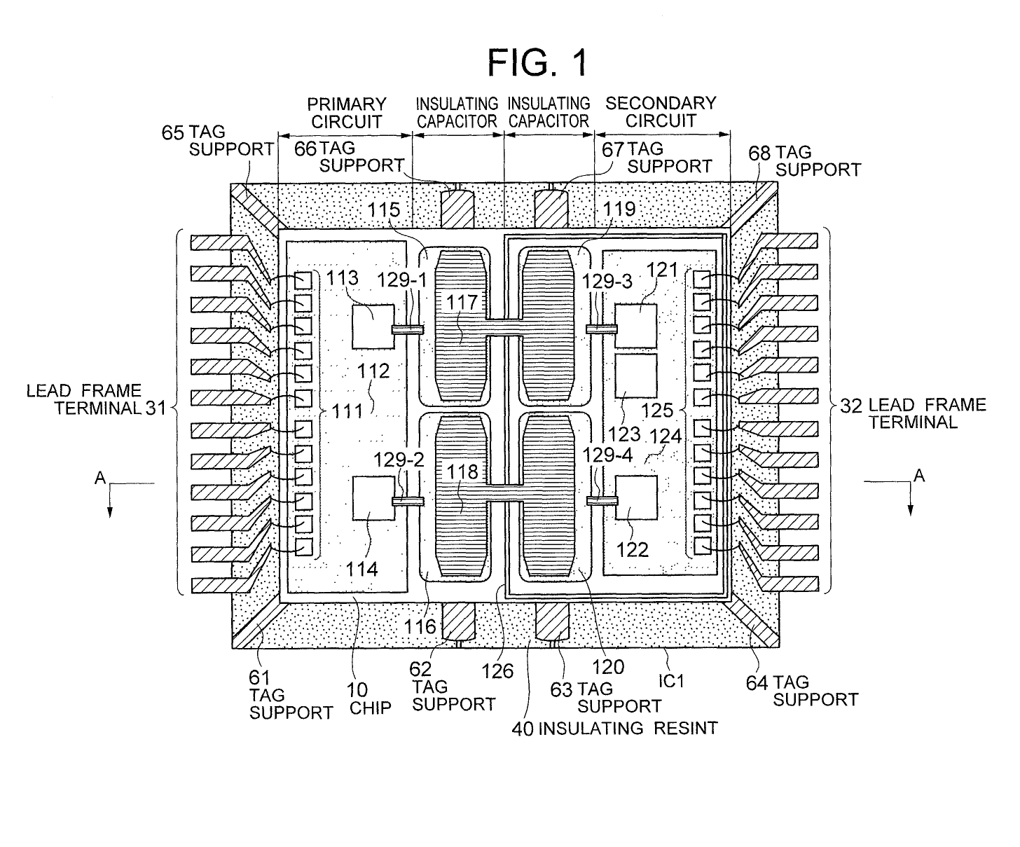

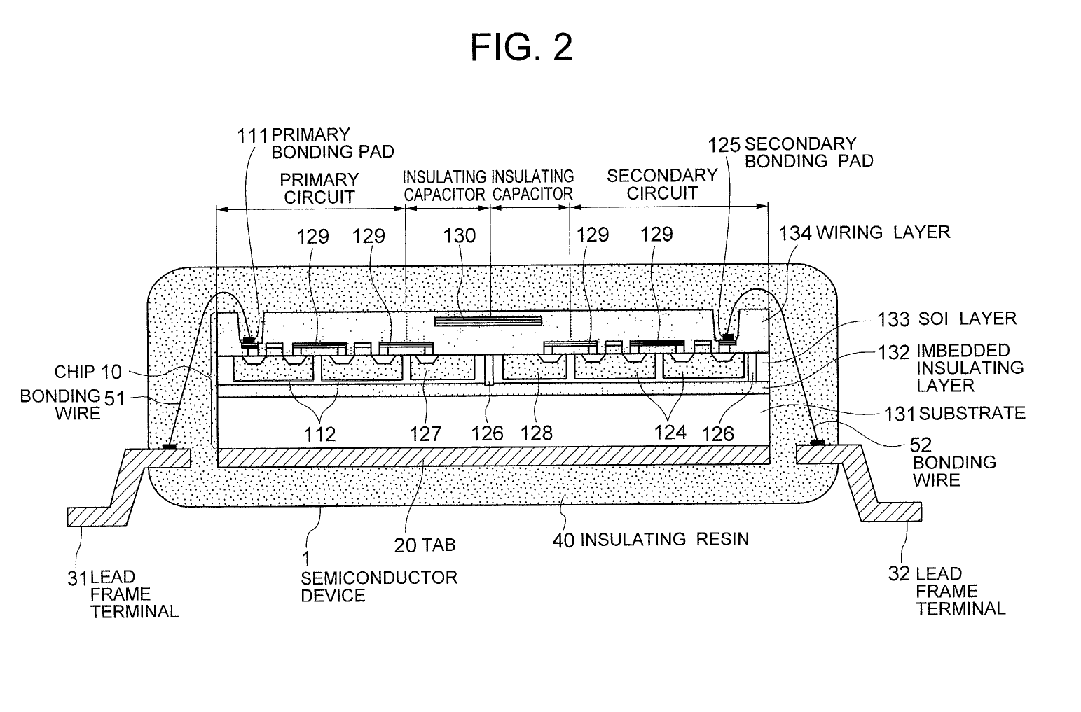

Hereinafter, a first embodiment of the present invention will be described with reference to FIGS. 1-10. FIG. 1 a plan view of the semiconductor device according to this embodiment, and FIG. 2 is a sectional view along a line A-A in FIG. 1. As shown in the figures, a semiconductor device 1 comprises: a semiconductor chip 10; a tab 20 for supporting the semiconductor chip 10 when packaging it; primary and secondary lead frame terminals 31 and 32 for inputting and outputting signals to and from the semiconductor chip 10; and insulating resin 40 for insulatingly fixing these components, as main components. The chip 10 is fixedly adhered to the tab 20, and fixedly supported by tab supports 61-68 when molding.

On the input side of the semiconductor chip 10 formed are primary bonding pads 111, a primary circuit 112, a driver circuit 113, a receiver circuit 114, insulating capacitors 115 and 116, and upper electrodes 117 and 118 of the insulating capacitors 115 and 116. On the output side of the semiconductor chip 10 formed are insulating capacitors 119 and 120, upper electrodes 117 and 118 of the insulating capacitors 119 and 120, a receiver circuit 121, a driver circuit 122, an insulating switch control circuit 123 which consists of a charge pump circuit, a secondary circuit 124, and secondary bonding pads 125.

Further, the input side circuit and the output side circuit are insulatingly isolated each other by an imbedded trench 126. Wirings 129-1 to 129-4 are wires for connecting the insulating capacitors 115, 120, 116 and 119 to the driver circuits 113 and 122 and the receiver circuits 114 and 121, respectively. Incidentally, the input-side upper electrodes and the output-side upper electrodes of the insulating capacitors are integrally formed on the same plane by upper wires (i.e., the upper electrodes 117 and 118).

As shown in the sectional view of FIG. 2, the chip 10 is fixedly adhered to the tab 20, and the lead frames 31 and 32 are connected to the bonding pads 111 and 125 of the chip 10 by bonding wires 51 and 52. Thereafter, the whole arrangement is molded by insulating resin 40 while exposing partially the lead frames.

The chip 10 is manufactured as follows. The primary and secondary circuits 112 and 124 and lower electrodes 127 and 128 of the insulating capacitors are formed on an SOI wafer by processes including photomask, etching, diffusion and film formation. Here, the primary and secondary circuits 112 and 124 includes transistors, resistors, capacitors, coils, wires and the like, and the SOI wafer includes a silicon substrate 131, an imbedded insulating layer 132, and an SOI layer 133. Thereafter, first and second wiring layers 129 and 130 are formed in two layers in the wiring layer 134. Then, holes for the bonding pads 111 and 125 are formed in an insulating material which forms the wiring layer 134.

The primary circuit 112 and the secondary circuit 124 formed on the chip 10 are strongly insulated each other by the imbedded insulating layer 132, the imbedded trench 126 formed in the SOI layer 133, and the insulating thin film forming the wiring layer 134. Further, the primary circuit 112 and the secondary circuit 124 are connected from the bonding pads 111 and 125 to the lead frames 31 and 32 via the bonding wires 51 and 52, respectively.

In the semiconductor device having the above construction, the capacitors are formed between the primary circuit 112 and the substrate 131 and between the secondary circuit 124 and the substrate 131. By using these capacitors and the insulating capacitors formed through the upper electrodes 117 and 118, it is possible to insulatingly isolate the primary circuit 112 and the secondary circuit 124 to capacitively couple them, as mentioned hereinafter. Incidentally, for the insulation isolation in the respective circuit regions formed in the chip 10, it is possible to use the usual PN junction isolation which is generally used in the low voltage LSI. However, the specific insulation isolation means such as a trench isolation using an SOI substrate or a dielectric isolation using a dielectric isolating substrate may be provided.

In this semiconductor device, it is possible to form a plurality of circuits on an SOI wafer having the structure, in which an insulating layer having a thickness of less than about 10 μm is sandwitched between a silicon substrate having a thickness of 100 μm order and a silicon layer having a thickness of less than about several tens μm, by using an SOI working process such that they are insulatingly isolated in the island shape. Further, it is possible to form the insulation isolation to bridge these circuits. In this semiconductor device, the insulating capacitors and the capacitors between the respective circuit regions and the substrate may be utilized when a control signal is transmitted from one circuit (the primary circuit 112) to the other circuit (the secondary circuit 124). Incidentally, in the figures as referred to hereinafter, the same components as those shown in FIGS. 1 and 2 are designated using the same reference numerals or symbols, and the detailed explanation thereof will be omitted.

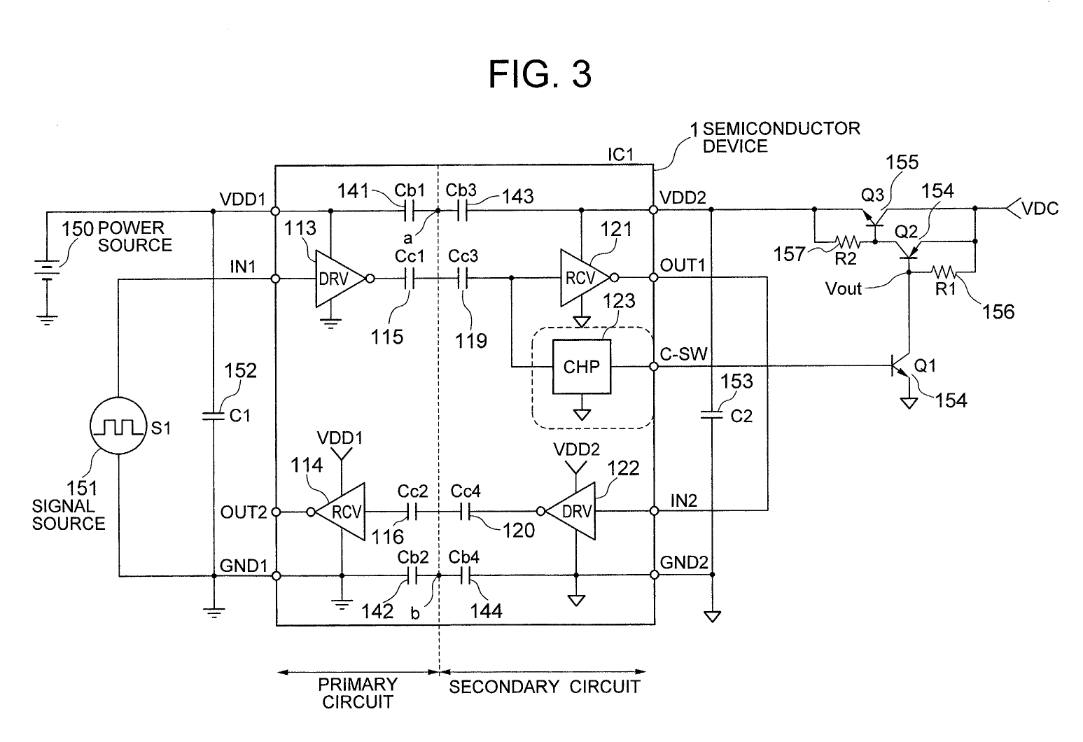

FIG. 3 shows an example in which the semiconductor device of this embodiment is applied to an insulating switch. In the figure, the insulating capacitors 115, 119, 116 and 120, which bridge the primary circuit and the secondary circuit, are represented by Cc1, Cc3, Cc2 and Cc4, respectively. Reference numerals 141 and 142 denote capacitors Cb1 and Cb2 disposed between the primary circuit region and the substrate, respectively. Reference numerals 143 and 144 denote capacitors Cb3 and Cb4 disposed between the secondary circuit region and the substrate, respectively. These capacitors Cb1-Cb4 indicate schematically the capacitors formed through the insulating substrate, and the path between the points “a” and “b” is electrically conductive through the silicon substrate 131. Further, these capacitors Cb1-Cb4 actually exist between the primary circuit and its power source terminal VDD1, between the primary circuit and its ground terminal GND1, between the secondary circuit and its power source terminal VDD2, and between the secondary circuit and its ground terminal GND2, respectively. (Although not shown in the figure, capacitors are formed between VDD1 and GND2 and between VDD2 and GND1, and generally Cc<Cb when formed on-chip.) Further, reference numeral 150 denotes a power source; 151 a signal source; 152 and 153 input capacitor C1 and output capacitor C2; 154, 155 and 156 transistors Q1, Q2 and Q3 forming insulating switches; and 157 and 158 resistors. This circuit provides a charge-pump circuit by combining the driver circuit (DRV) 113, the insulating switch control circuit (CHP) 123, the insulating capacitors Cc and capacitors Cb between the circuits within the SOI layer and the substrate.

In this embodiment, the components are arranged as shown, so that it is possible to set the power source 150 to voltage 3 V, the signal of the signal source 151 to a pulse signal of 10 MHz, C1 to 0.1 μF, C2 to 1 μF, R1 and R2 each to 30 kΩ, and to apply 3.5V to the VDD2 terminal. Further, by isolating the insulating switch control circuit 123 from the other circuits by the imbedded trench, the insulating switch control circuit 123 can be located freely anywhere, thereby realizing a high side switch.

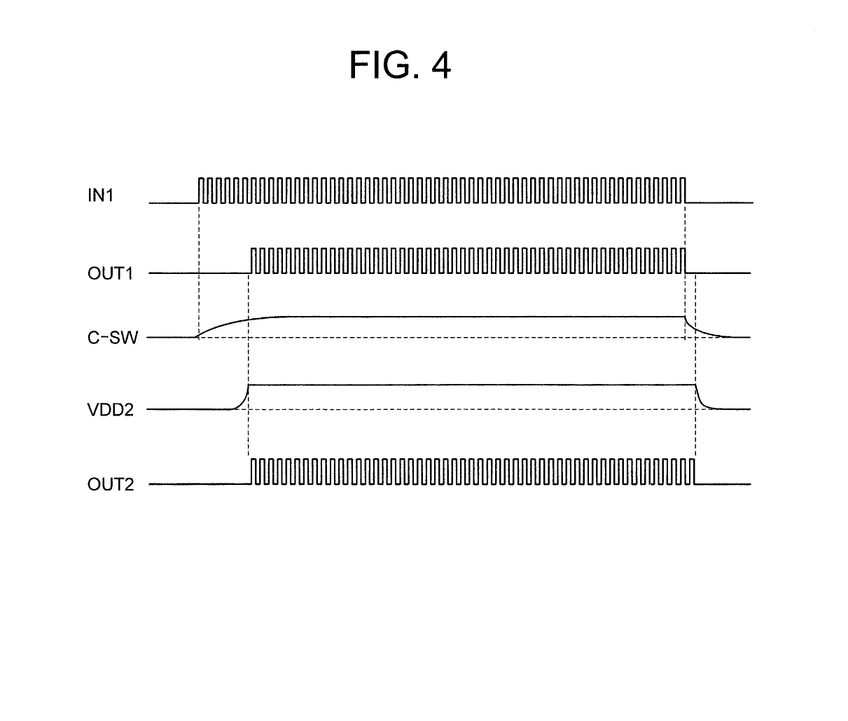

FIG. 4 illustrates the operation of the circuit shown in FIG. 3. As shown in the figure, a signal pulse IN1 is supplied from the signal source 151. The insulating switch control circuit 123 receives the signal pulse IN1 through the driver 113 and the capacitors Cc1 and Cc3 to gradually increase its output C-SW. When the signal pulse IN1 stops, the insulating switch control circuit 123 gradually decrease its output C-SW. That is, when the output CSW rises, the external switch element Q1 turns on. As a result, the transistors Q2 and Q3 turn on successively, so that the power source VDC is supplied to the receiver circuit 121, and then the input signal (signal pulse) IN1 appears at an output terminal OUT1.

Similarly, after the power source VDC is supplied to the driver circuit 122, a signal pulse IN2 of the secondary circuit appears at an output terminal OUT2 through the capacitors Cc4 and Cc2 and the receiver circuit 114.

When the pulse signal IN1 from the primary circuit stops, the output C-SW is reduced, so that the transistors Q1, Q2 and Q3 are turned off. As a result, the power source is turned off to stop the output OUT1 of the receiver circuit 121 and the input IN2 of the driver circuit 122. Incidentally, the pulse signal IN1 is not necessarily a continuous pulse signal. However, since the output C-SW rises more rapidly as the pulse signal varies more frequently from “0” to “1” or from “1” to “0”, it is possible to obtain a desired output by suitably selecting the circuit constants while considering the signal type and the rate of the pulse variation.

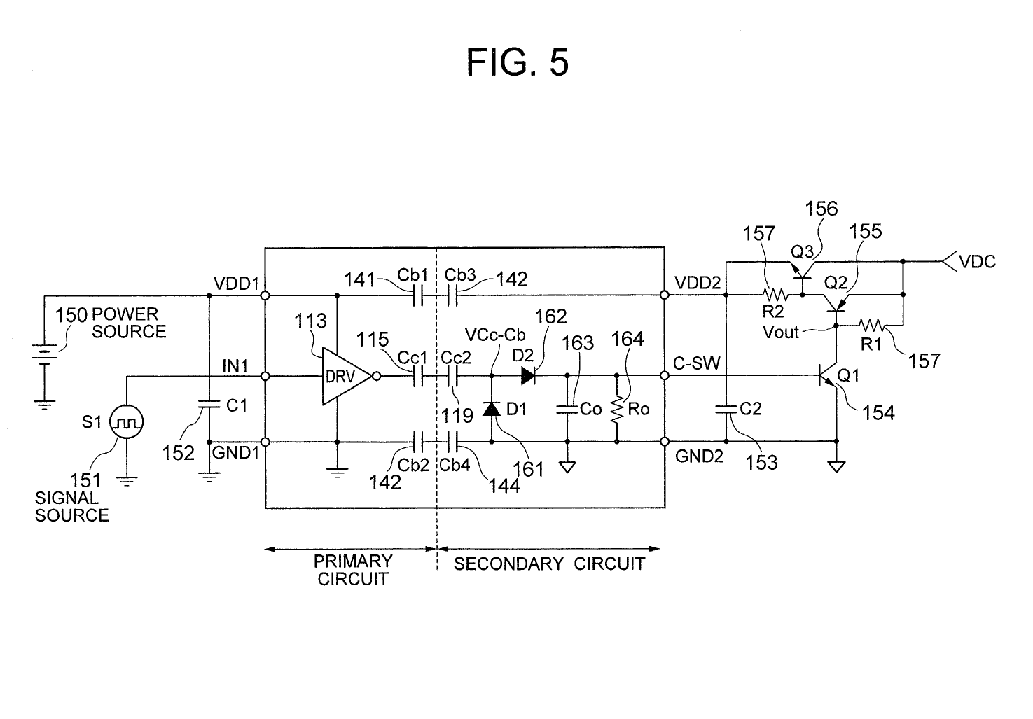

FIG. 5 shows another example in which the semiconductor device is applied to an insulating switch circuit. In the figure, reference numerals 161 and 152 denote diodes D1 and D2; 163 a capacitor Co; and 164 a resistor Ro. These components constitute the insulating switch control circuit 123 which consists of a charge pump circuit.

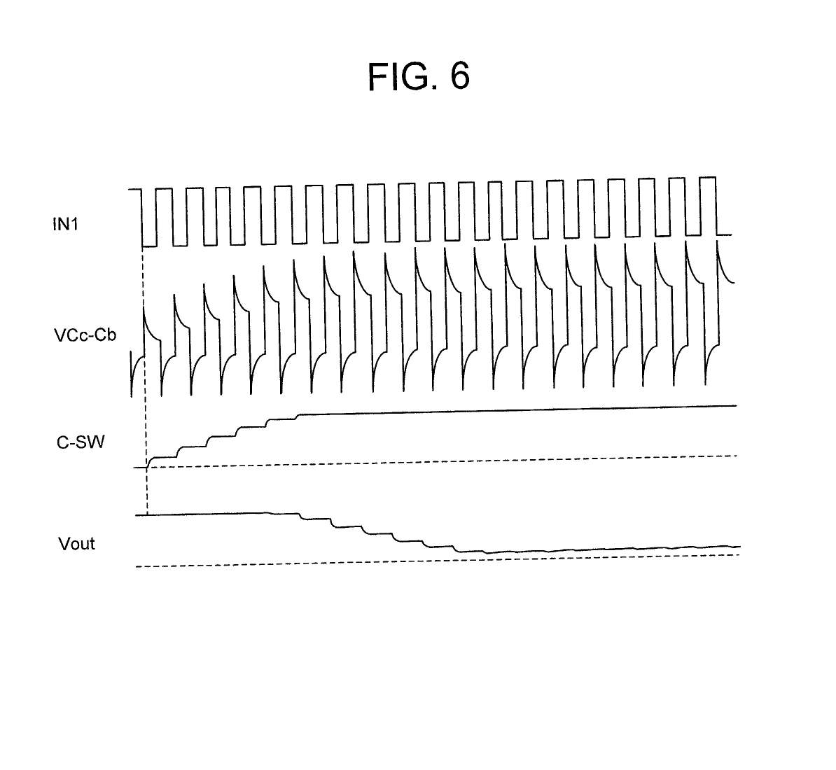

FIG. 6 shows a diagram explaining the operation of the insulating switch circuit shown in FIG. 5. This circuit performs the charge-pump operation with an input capacitor which is equal to the equivalent series capacitor Cp of the capacitors Cb and Cc (since Cc<<Cb, substantially Cp=Cc). When a signal pulse IN1 is inputted as an input signal, the input capacitor Cp is charged through the diode D1 to a voltage equal to the input voltage upon the leading edge of the input pulse IN1. At the trailing edge of the input voltage IN1, an output capacitor Co is charged by the electric charge of the capacitor Cp through the diode D2. If no loss occurs during this transfer of the electric charge, the electric charge of Cp×VDD1 is accumulated in the capacitor Co, so that an output voltage C-SW is changed to VDD1×Cp/Co. By repeating this operation, the electric charges are accumulated in the output capacitor Co. However, as the voltage of the output capacitor Co increases with the accumulation of the electric charges, the amount of electric charges as transferred decreases. At the steady state, the electric charges corresponding to the output current (i.e. the base current of a transistor Q1 and the current flowing through the resistor Ro) are transferred. As the output voltage C-SW increases with the accumulation of the electric charges, the transistor Q1 is biased in the ON direction. When the output voltage C-SW increases to a voltage higher than the threshold voltage, the transistors Q1, Q2 and Q3 are turned on, so that a power source voltage VDC is applied to the semiconductor device. Thus, the insulating switch function is realized.

In this embodiment, the primary circuit and the secondary circuit are coupled by using the capacitor Cb, which is formed between the semiconductor substrate 131 and the primary or secondary circuit formed in the SOI layer substrate 133, and the capacitor Cc formed through the upper electrode 117 or 118. As a result, it is possible to provide an isolator or an insulating switch circuit in which the primary circuit and the secondary circuit are insulatingly isolated. Further, since the capacitor Cb is utilized, it is enough to form only the capacitor Cc as the insulating capacitor actually formed. Therefore, it is possible to form a single-ended driving insulating switch in a small size on chip.

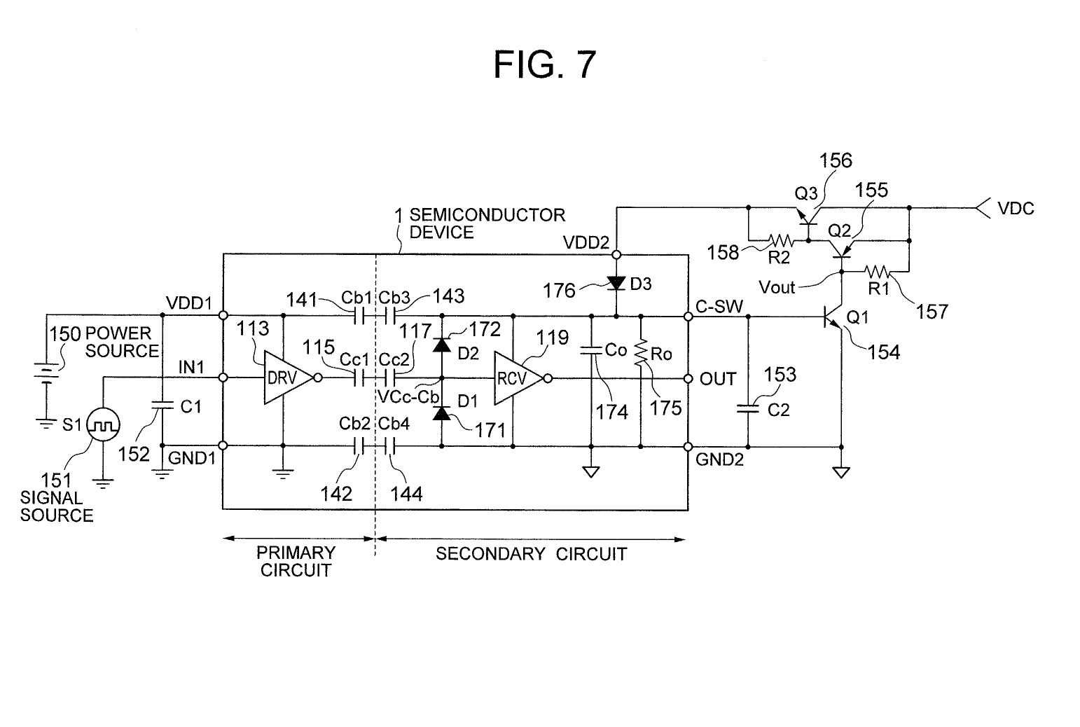

FIG. 7 shows still another example in which the semiconductor device is applied to the insulating switch circuit. In the figure, reference numerals 171, 172 and 176 denote diodes D1, D2 and D3, 174 a capacitor Co; and 175 a resistor Ro. These components constitute the insulating switch control circuit 123 which consists of a charge pump circuit.

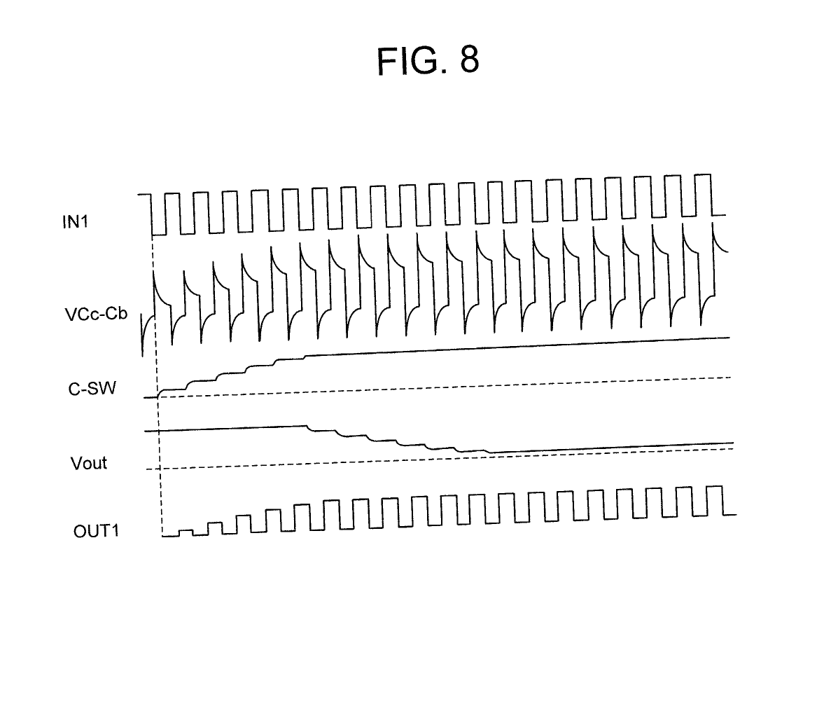

FIG. 8 illustrates the operation of the insulating switch circuit shown in FIG. 7. The operation of this circuit is substantially the same as that of the circuit shown in FIG. 5. However, since the output voltage of the insulating switch is supplied to the receiver circuit 119 as a power source, it is possible to obtain an isolator output of voltage which follows the variation of the power source voltage, in synchronism with the leading edge of the power source.

As shown in the figure, the external switch elements Q1-Q3 are driven by the output voltage C-SW to connect the power source voltage VDC to the power source terminal VDD2 through the insulating switch Q3. Thereby, it is possible to obtain an isolator output OUT independent of the charge pump output voltage after connecting. Incidentally, in order to turn off the insulating switch Q3, the receiver circuit and the C-SW circuit may be arranged so as to be electrically separable. However, in the circuit as shown, it may be arranged such that the pulse input supplied to the transistor Q1 can be stopped by a suitable off means (not shown) after starting.

In this embodiment, the primary and secondary circuits are connected by using the capacitor Cb formed between the semiconductor substrate 131 and the primary or secondary circuit formed within the SOI substrate 133, and the capacitor Cc formed through the upper electrode 117 or 118. Thereby, it is possible to constitute the insulating switch circuit in which the primary circuit and the secondary circuit are insulatingly isolated each other. Further, since the capacitor Cb is utilized, it is enough to actually form only the capacitor Cc. Thereby, it is possible to realize the single-ended driving insulating switch or the isolator in a small size on chip.

Further, when the charge pump is formed by utilizing the capacitor Cb, it is possible to supply the voltage to the power source of the secondary circuit by utilizing a protective diode 176, which is located on the receiver side of the insulating switch, to operate the insulating switches Q1-Q3 disposed on the secondary side by using this power source. With this arrangement, the charge pump circuit can be formed while reducing the number of the elements to be used exclusively for the insulating switch, so that it is possible to prevent the chip area from being increased. As a result, it is effective to make the IC area smaller. Further, in FIG. 7, if the charge pump output is set larger, it is possible to operate the device without the external power source supplied through the diode D3. That is, it is possible to realize the insulating switch which can be turned on and off by operating the insulating switch with a power transmitted through the charge pump circuit.

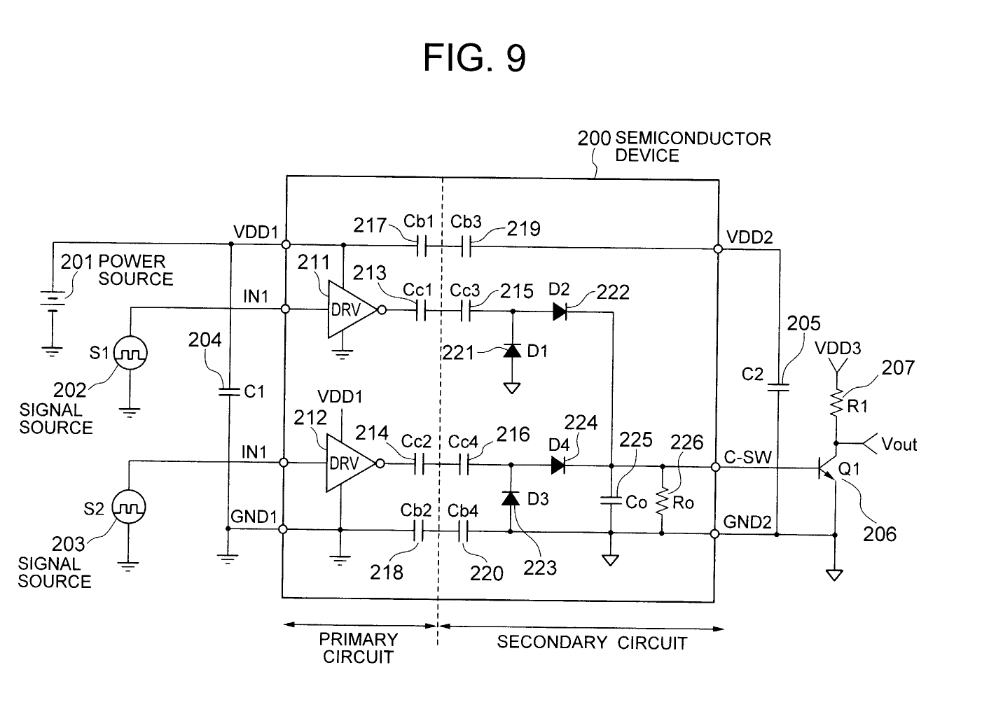

FIG. 9 shows still further example in which the semiconductor device is applied to the insulating switch. In the figure, reference numerals 200 denotes a semiconductor switch; 201 a power source; 202 and 203 transmitting signal sources S1 and S2; 204 and 205 input capacitor C1 and output capacitor C2; 206 a transistor Q1; and 207 a resistor R1. Reference numerals 211 and 212 denote driver circuits; 213, 214, 215 and 216 insulating capacitors Cc1, Cc2, Cc3 and Cc4; 217 and 218 capacitors Cb1 and Cb2 formed between the semiconductor substrate and the primary circuit formed in the SOI layer; 219 and 220 capacitors Cb3 and Cb4 formed between the semiconductor substrate and the secondary circuit formed in the SOI layer; 221, 222, 223 and 224 diodes D1, D2, D3 and D4; 225 a capacitor Co; and 226 a resistor Ro.

The components of the driver 211, capacitors Cc1, Cc3 and Cb1-Cb4 and diodes D1 and D2, and the components of the driver 212, capacitors Cc2, Cc4 and Cb1-Cb4 and diodes D3 and D4 constitute two charge pumps with the common capacitor Co and resistor Ro, respectively. The outputs of the charge pumps are connected through a C-SW terminal to the base of the transistor Q1. Further, since the capacitors Cb1-Cb4 are schematically shown, the capacitors existing between VDD1 and GND2 and between VDD2 and GDN1 are omitted from the figure.

As above-mentioned, since this embodiment constitutes the multi-channel, it is possible to collect the charge pump outputs of the respective channels at the output capacitor Co to transmit power multiplied by the number (N) of channels. Therefore, if the load is unchanged, it is possible to rise the voltage at the rate of N times. This charge pump can be used when a driver is inserted into the secondary side or a protective diode is utilized like FIG. 7.

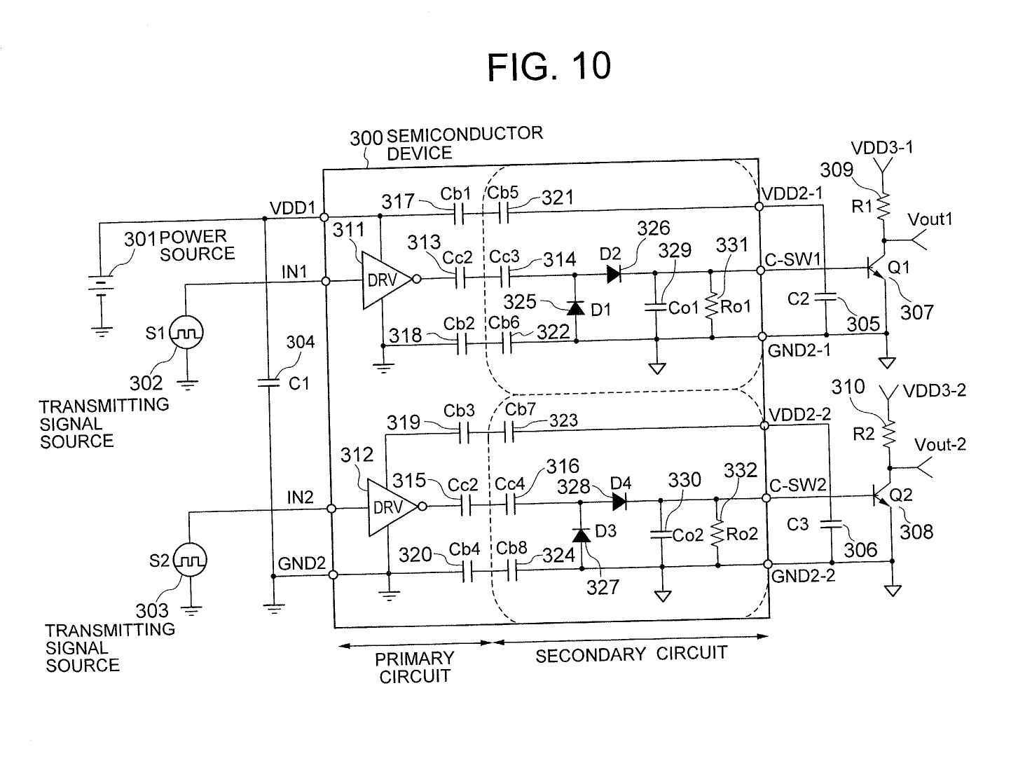

FIG. 10 shows still another example in which the semiconductor device is applied to the insulating switch circuit. In the figure, reference numeral 300 denotes a semiconductor switch; 301 a power source; 302 and 303 transmitting signal sources S1 and S2; 304 an input capacitor Cl; 305 and 306 output capacitors C2 and C3; 307 and 308 transistors Q1 and Q2; 309 and 310 resistors R1 and R2; 311 and 312 driver circuits; 313, 314, 315 and 316 insulating capacitors Cc1, Cc2, Cc3 and Cc4; 317, 318, 319 and 320 capacitors Cb1, Cb2, Cb3 and Cb4 which are formed between the semiconductor substrate and the primary circuit formed in the SOI layer; 321, 322, 323 and 324 capacitors Cb5, Cb6, Cb7 and Cb8 which are formed between the semiconductor substrate and the secondary circuit formed in the SOI layer; 325, 326, 327 and 328 diodes D1, D2, D3 and D4; 329 and 330 capacitors Co1 and Co2; and 331 and 332 resistors Ro1 and Ro2.

The components of the driver 311, capacitors Cc1, Cc3, Cb1, Cb2, Cb5 and Cb6, diodes D1 and D2, capacitor Co1, and resistor Ro1 constitute the first charge pump circuit. The components of the driver 312, capacitors Cc2, Cc4, Cb3, Cb4, Cb7 and Cb8, diodes D3 and D4, capacitor Co2, and resistor Ro2 constitute the second charge pump circuit. Further, the output sides of the respective charge pumps are insulated from other circuits by imbedded trenches shown by broken lines. Furthermore, the outputs C-SW1 and C-SW2 of the respective charge pumps are connected to the bases of the transistors Q1 and Q2 acting as switching elements, respectively. According to this embodiment, since the respective channels in the multichannel structure are insulated each other by the imbedded trenches, it is possible to arrange the respective insulating switches in the circuits having the different potentials. For this reason, when the power source voltage and the current detected from a motor are supplied to a low-voltage control circuit, it is possible to arrange the respective insulating switches in the high-voltage power source circuit and the low-voltage control circuit. In this case, it is also possible to use the capacitors, which are formed between the semiconductor substrate and the primary and secondary circuits, as the insulating capacitors on the one side. Incidentally, this charge pump is also applicable to the case in which the driver is inserted on the secondary side like FIG. 7 or to the case in which the protective diode is utilized.

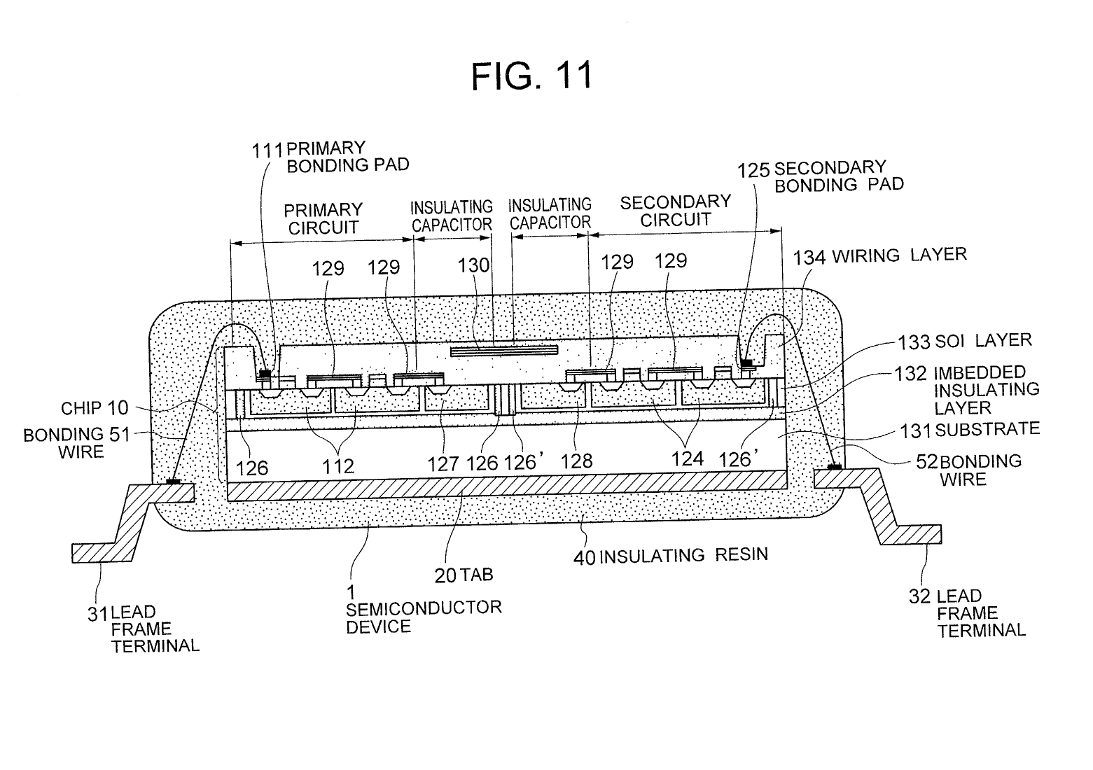

FIG. 11 shows a second embodiment of the present invention. In the figure, the construction other than the imbedded trenches 126 is the same as that of FIGS. 1 and 2. In this embodiment, the imbedded trench 126 is arranged to surround the primary circuit 112 and the lower electrode of the insulating capacitor. Further, the imbedded trench 126′ is arranged to surround the secondary circuit 124 and the lower electrode 128 of the insulating capacitor. With this construction, the insulation between the circuit regions is made much stronger. Further, it is possible to form the third circuit region by using these imbedded trenches. It is also possible to use the capacitors between the semiconductor substrate and the primary and secondary circuits as the insulating capacitors on the one side.

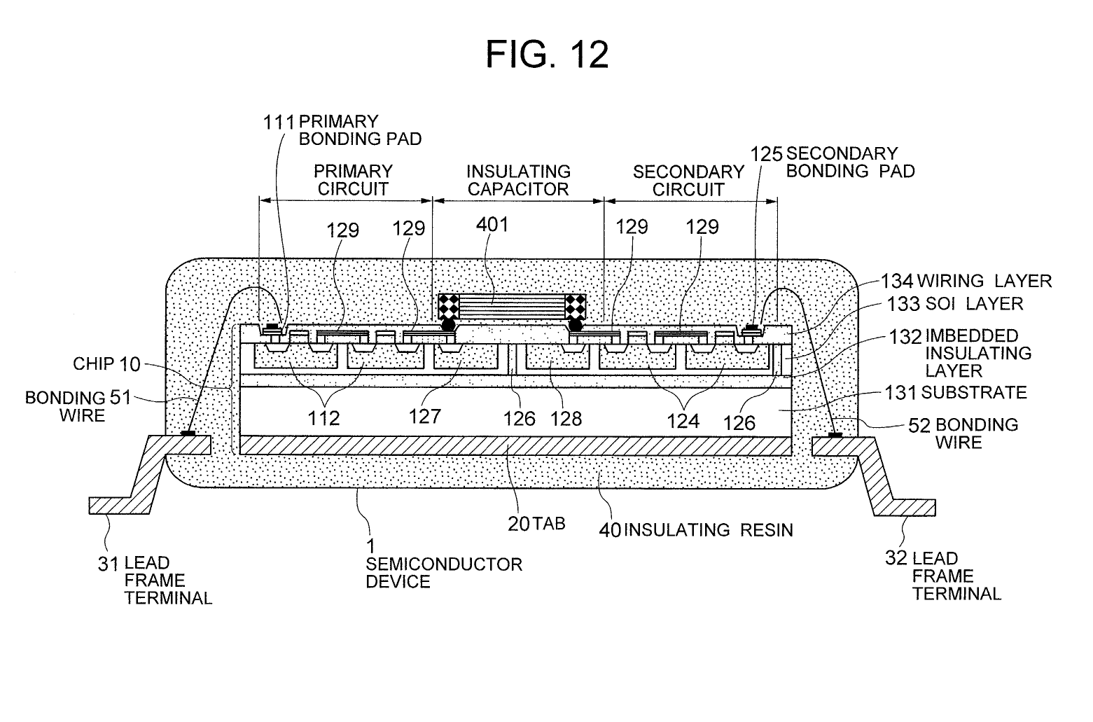

FIG. 12 shows a third embodiment of the present invention. In the figure, the construction other than the imbedded trenches 126 is the same as that of FIGS. 1 and 2. In this embodiment, the insulating capacitor Cc is disposed as a separate chip 401 as shown. With this construction, it is possible to set a capacitance value independent of the chip space, so that the scope in which it is applied as the insulating switch can be expanded. Further, in such a case, it is also possible to use the capacitors between the semiconductor substrate and the primary and secondary circuits as the insulating capacitors on the one side.

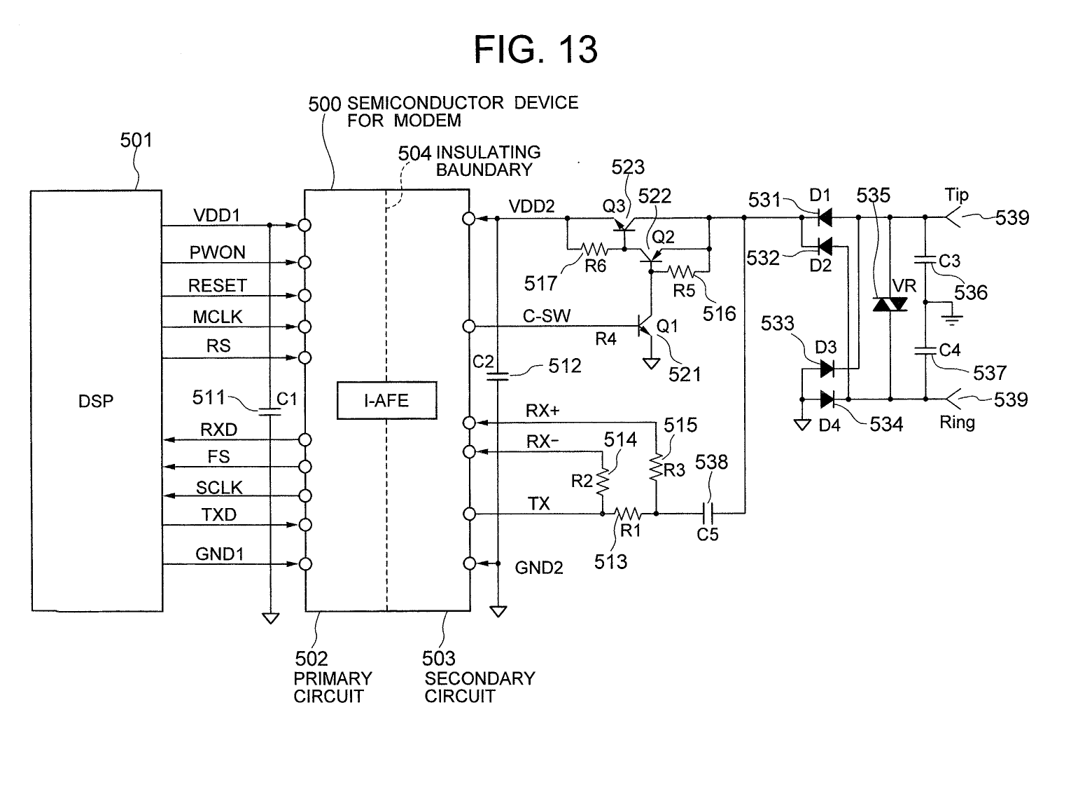

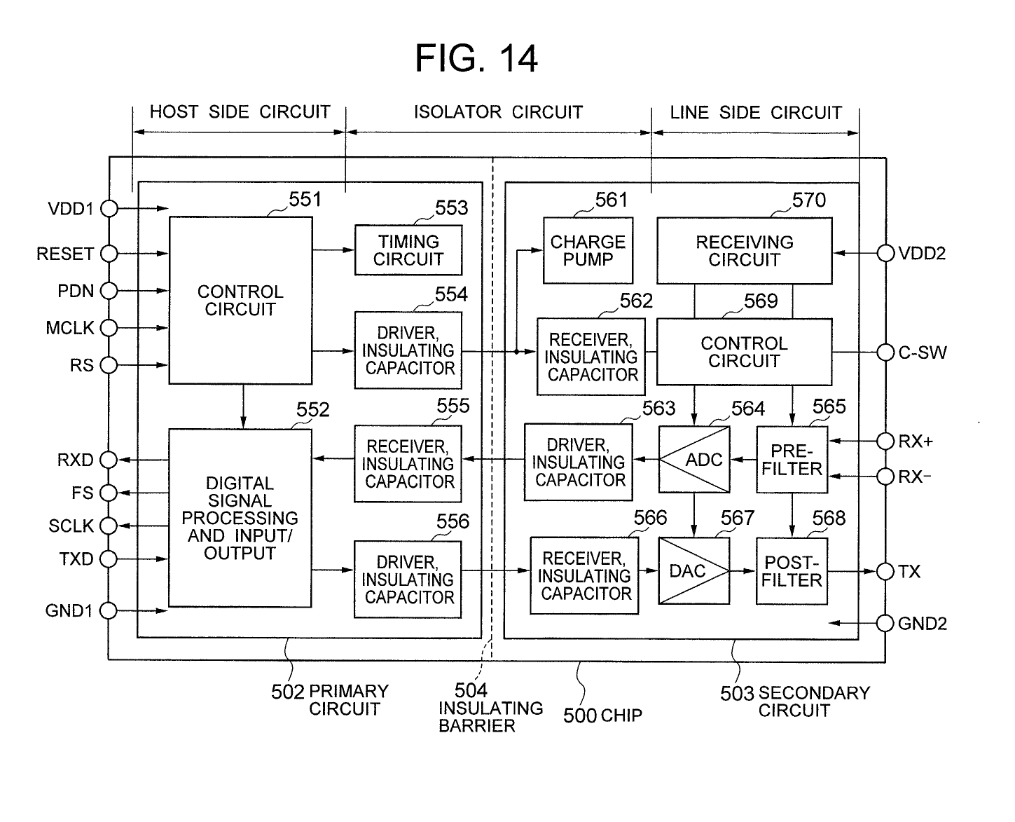

FIGS. 13 and 14 are diagrams illustrating an example in which a semiconductor device for modem according to the present invention is applied to a modem device. FIG. 13 shows a system construction of the modem device using the semiconductor device for modem according to the present invention. FIG. 14 shows the internal construction of the semiconductor device for modem (AFE500) according to the present invention.

In FIG. 13, reference numeral 500 denotes the semiconductor device for modem as above-mentioned. Reference numeral 501 denotes a signal processor (DSP); 502 and 503 primary and secondary circuits of the semiconductor device for modem; 504 an insulating boundary of the semiconductor device for modem; 511 and 512 capacitors C1 and C2; 513-517 resistors R1-R6; 521-523 transistors Q1-Q3; 531-534 diodes D1-D4; 535 a varistor; 536 and 537 capacitors C3 and C4; 539 and 540 terminals Tip and Ring which are connected to a telephone circuit.

FIG. 14 shows the internal construction of the semiconductor device 500 for modem. Reference numeral 551 denotes a control circuit for the whole semiconductor device for modem, 552 a digital filter and input/output circuit, 553 a timing circuit, 554 a driver and insulating capacitor, 555 a receiver and insulating capacitor, and 556 a driver and insulating capacitor. These components constitute the primary circuit 502. Reference numeral 561 denotes a charge pump circuit, 562 a receiver and insulating capacitor, 563 a driver and insulating capacitor, 564 a circuit (ADC) for converting an analog signal to a digital signal, 565 a pre-filter, 566 a receiver and insulating capacitor, 567 a circuit (DAC) for converting a digital signal to an analog signal, 568 a post-filter, and 569 a receiving circuit. These elements constitute the secondary circuit 503. The driver and insulating capacitor 554 and the receiver and insulating capacitor 562 constitute an isolator circuit provided in a path for a control signal. The driver and insulating capacitor 563 and the receiver and insulating capacitor 555 constitute an isolator circuit provided in a path for a receiving signal. The driver and insulating capacitor 556 and the receiver and insulating capacitor 566 constitute an isolator circuit provided in a path for a transmitting signal. All of the control, receiving and transmitting signals are digital signals.

Now the operation of the modem will be explained with reference to FIG. 13. The DSP 501 is connected to a communication terminal (not shown) to obtain the communication condition and generate a control instruction. The DSP 501 receives the control information from the communication terminal to control the semiconductor device for modem. The DSP 501 also receives transmission information to modulate it by the digital signal processing. The modulated transmission information is supplied to the semiconductor device for modem 500. The DAC 567 in the semiconductor device for modem converts the modulated transmission information to an analog signal to transmit it to the telephone circuit. On the other hand, the analog signal from the telephone circuit is received in the semiconductor device for modem 500. The received analog signal is converted to a digital signal in the ADC 564 to be supplied to the DSP 501. The digital signal is demodulated by the digital signal demodulation processing to be returned to the communication terminal as a receiving data. That is, the semiconductor device for modem 500 is an analog front-end semiconductor device having the isolator function between the telephone circuit and the communication terminal and the interconversion function between the analog signal and the digital signal. In order to connect the modem circuit to the communication circuit before starting the communication, the DSP 501 pulse-drives the driver 554 through the control circuit 551 provided in the primary circuit 502 within the semiconductor device for modem 500. This pulse is also used as a main timing clock for the secondary circuit 503. In this embodiment, this pulse is at 24,576 MHz and inputted to the charge pump circuit of the secondary circuit 503 through the insulating capacitor Cc of the receiver 562. At this time, no power is supplied to the secondary circuit 502, which therefore acts no operation with any input signal. When a pulse is applied to the charge pump circuit, an output voltage C-SW is produced. As the output voltage C-SW increases, the transistor Q1 turns on and the transistors Q2 and Q3 also turn on as mentioned before, so that a DC voltage from the telephone circuit is applied to the terminal VDD2. The receiving circuit in the semiconductor device for modem 500 reduces the voltage at the terminal VDD2 to a level at which the semiconductor device for modem operates normally, and supplies the reduced voltage to the secondary circuit 503. At the leading edge of this internal voltage, the circuit is subjected to the initial reset. Further, a clock pulse is supplied to the control circuit 569, so that the control information is supplied to the whole secondary circuit 503. Since the rising of the power source voltage and the supply of the control information are finished in about 1 ms, no problem exists in the operation of the communication process. After the rising of the power source voltage, it can operate as modem by the well-known DSP digital signal processing and controlling, and the ADC and DAC functions of the semiconductor device for modem.

In the semiconductor device for modem of this embodiment, the charge pump and three sets of isolators are arranged by using the large capacitors between substrates utilizing the whole semiconductor, as the other insulating capacitor. For this reason, it is possible to omit the process for manufacturing the capacitor between substrates to provide the large effects in reduction of the chip size and the cost.

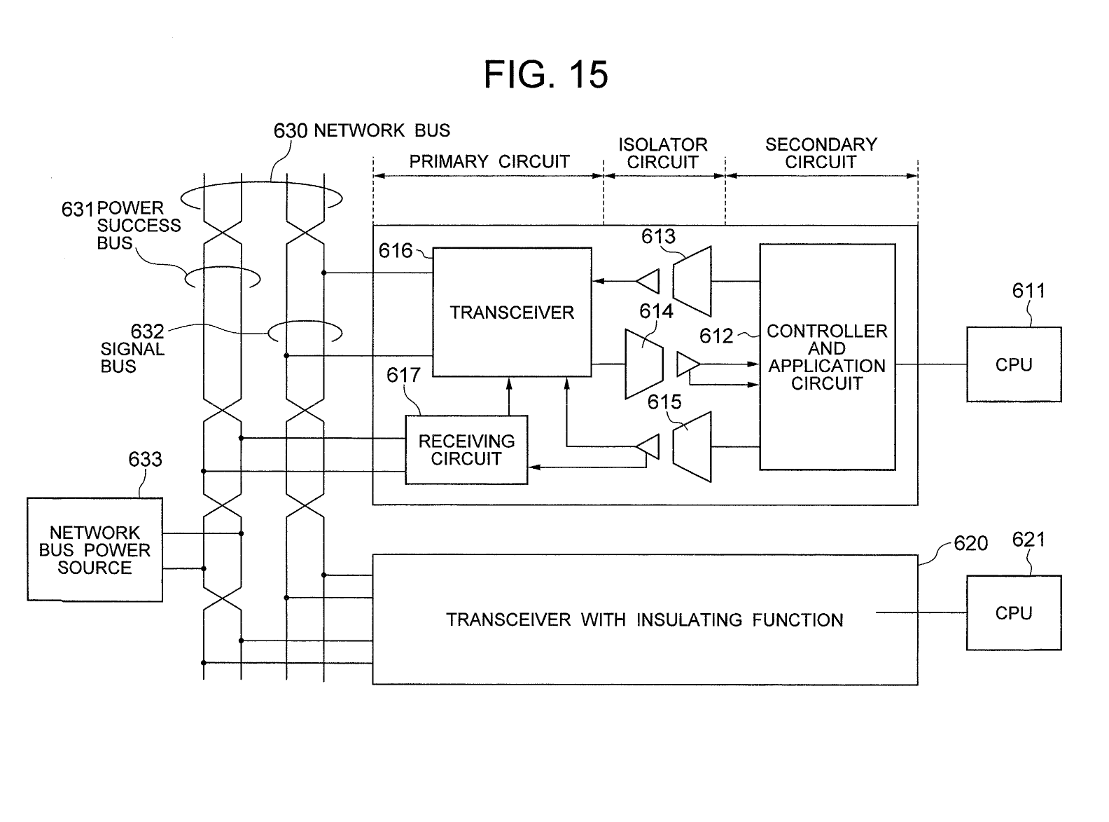

FIG. 15 shows an example of a network system using transceiver LSI's 610 and 620 each using the semiconductor device according to the present invention. In the figure, reference numeral 612 denotes a controller and application circuit, 613-615 isolator circuits, 616 a transceiver circuit, and 617 a receiving circuit. These elements constitute the transceiver LSI 610. Reference numeral 620 denotes a similar transceiver LSI, although its internal construction is not shown. The transceiver LSI's 610 and 620 are connected in parallel to a network bus 630. The network bus 630 includes a power source bus 631, a signal bus 632 and a control signal bus (not shown), and a network bus power source 633 is connected to the power source bus 631. The controller and application circuit 612 in each of the transceiver LSI's 610 and 620 is insulatingly isolated from the transceiver circuit 616 and the receiver circuit 617 by the isolator circuits 613-615. The transceiver 616 receives a power from the power source bus 631 through the receiving circuit 617. The receiving signal from the signal bus 632 is transmitted to the CPU 611 through the transceiver circuit 616, the isolator circuit 614 and the controller and application circuit 612 in that order. Further, the transmitting signal from the CPU 611 is transmitted to the signal bus 632 through the controller and application circuit 612, the isolator circuit 615 and the transceiver 632.

When the communication is to be made between the transceiver LSI 610 and the transceiver LSI 620, the transceiver in the transceiver LSI on the active side is released from the standby condition. Then, the receiving signal on the signal bus 632 is monitored to detect the blank state of the signal bus 632, and the transmitting signal addressed to the other transceiver LSI is transmitted. The other transceiver LSI releases its standby condition at intervals to monitor the receiving signal and the state of the control signal bus (not shown). When the other transceiver LSI confirms a signal addressed to itself, it continues receiving the signal. Incidentally, the insulating switch circuits shown in FIG. 7 are incorporated in the isolators 614 and 615 of the transceiver LSI 610. Therefore, it is possible to remotely control the power source of the CPU by activating the power source in the controller 612 by the control signal from the control bus (not shown). On the other hand, it is possible to operate the receiving circuit by operating the insulating switch of the isolator 615 from the CPU side through the controller 312. It is possible to save the electric power consumed in the network system by closely controlling the power consumption by the above processing. These advantageous effects can be obtained by realizing the incorporation of the insulating switch and its application circuit into the transceiver of the present embodiment by using a small chip area.

As above-mentioned, according to the present invention, it is possible to provide the isolator in a less mounting area by utilizing the insulating capacitor formed in the wiring layer and the capacitor between the circuit area and the substrate. Further, it is possible to form the insulating switch and its application circuit in a less mounting area by using this isolator.

What is claimed is:

1. A semiconductor device comprising:
an imbedded insulating layer formed in a semiconductor substrate;
at least two electric circuits formed on said imbedded insulating layer so as to be insulated each other, and capacitively coupled through said semiconductor substrate; and
a wiring layer formed on said electric circuits, and including inside electrodes which are capacitively coupled to said electric circuits;
wherein said electric circuits are connected through capacitors formed through said semiconductor substrate and capacitors formed through said electrodes.

2. A semiconductor device according to claim 1, wherein one of said electric circuits is a driver circuit for generating an alternating wave, and another electric circuit is a charge pump circuit.

3. A semiconductor device according to claim 2, wherein said charge pump circuit controls a switch circuit which turns on and off a power source of said other electric circuit.

4. A semiconductor device according to claim 1, wherein said semiconductor substrate includes a trench for insulatingly separating said electric circuits.

5. A semiconductor device according to claim 1, wherein one of said electric circuits is a driver circuit for transmitting a signal, and another electric circuit is a receiver circuit.

6. A semiconductor device according to claim 1, wherein a number of said capacitively-coupled electric circuits is more than two.

7. A semiconductor device comprising:
an imbedded insulating layer formed in a semiconductor substrate;
a plurality of electric circuits formed on said imbedded insulating layer so as to be insulated each other, and capacitively coupled through said semiconductor substrate; and
wiring layers formed on said electric circuits, and including inside capacitors connected to said electric circuits,
wherein said electric circuits are coupled through said capacitors and through capacitors which are formed through said semiconductor substrate.
